(19) United States
(12) Patent Application Publication
(10) Pub. No.: US 2016/0073466 A1
(43) Pub. Date: Mar. 10, 2016

(54) OUTPUT CIRCUIT AND LIGHT COUPLING DEVICE

(71) Applicant: KABUSHIKI KAISHA TOSHIBA, Tokyo (JP)

(72) Inventor: Yukio TSUNETSUGU, Buzen Fukuoka (JP)

(21) Appl. No.: 14/633,800

(22) Filed: Feb. 27, 2015

(30) Foreign Application Priority Data
Sep. 5, 2014 (JP) 2014-180992

(51) Int. Cl. H05B 33/08; H03K 17/16; H03K 3/012

(52) U.S. Cl. CPC H05B 33/0854; H03K 3/012; H03K 17/162

(57) ABSTRACT

An output circuit for receiving an input signal and outputting an output signal is provided. The output circuit includes an input terminal, an output terminal, a power supply terminal, a reference potential terminal, an output unit, a first drive circuit, and a second drive circuit. The output unit includes a first transistor, a first capacitance element, a second transistor, and a second capacitance element. The first transistor is connected between the power supply terminal and the output terminal. The first capacitance element is connected between a gate and the drain of the first transistor. The second transistor is connected between the reference potential terminal and output terminal. The second capacitance element is connected between a gate and the drain of the second transistor. The first and second drive circuits are configured to drive the first and second transistor respectively based on a voltage at the gate of the other transistor.

### CROSS-REFERENCE TO RELATED APPLICATION

This application is based upon and claims the benefit of priority from Japanese Patent Application No. 2014-180992, filed Sep. 5, 2014, the entire contents of which are incorporated herein by reference.

### FIELD

Embodiments described herein relate generally to an output circuit and a light coupling device.

### BACKGROUND

In general, various functional blocks are included in a mixed signal circuit in which a logic circuit and an analog-digital circuit are combined. For improved integration and function of a semiconductor integrated circuit device, there is a strong preference for transmitting digital data within the functional block, between the functional blocks, or even between devices in a system, at a high speed and at a low noise level. Also, there is a strong demand for low power consumption. In order to achieve signal transmission at a high speed and at a low noise level across various interfaces, a slew rate control output circuit that outputs a signal at a constant slew rate (a maximum rate of voltage change per unit time) is proposed. However, it is difficult to drive a wide range of load capacitors with low power consumption in such a device.

### DESCRIPTION OF THE DRAWINGS

FIG. 1 is a circuit diagram illustrating a slew rate control output circuit according to a first embodiment.

FIG. 2 is a circuit diagram for illustrating an operation of the slew rate control output circuit of FIG. 1.

FIG. 3 is a circuit diagram for illustrating an operation of the slew rate control output circuit of FIG. 1.

FIG. 4 is an operation waveform diagram for illustrating an operation of the slew rate control output circuit of FIG. 1.

FIG. 5 is an operation waveform diagram illustrating an operation state of the slew rate control output circuit of FIG. 1.

FIG. 6 is a circuit diagram illustrating a slew rate control output circuit according to a second embodiment.

FIG. 7 is an operation waveform diagram for explaining an operation of the slew rate control output circuit of FIG. 6.

FIG. 8 is an operation waveform diagram illustrating an operation state of the slew rate control output circuit of FIG. 6.

FIG. 9 is an operation waveform diagram illustrating an operation state of the slew rate control output circuit of FIG. 6.

FIG. 10 is an operation waveform diagram illustrating an operation state of the slew rate control output circuit of FIG. 6.

FIG. 11 is an operation waveform diagram illustrating an operation state of the slew rate control output circuit of FIG. 6.

FIG. 12 is a circuit diagram illustrating a slew rate control output circuit according to a third embodiment.

FIG. 13 is a circuit diagram illustrating a slew rate control output circuit according to a fourth embodiment.

FIG. 14 is an operation waveform diagram illustrating an operation state of the slew rate control output circuit of FIG. 13.

FIG. 15A is a block diagram illustrating a light coupling device according to a fifth embodiment.

FIG. 15B is a cross-sectional view illustrating a structure of the light coupling device according to the fifth embodiment.

FIG. 16 is a block diagram illustrating a light communication system according to a sixth embodiment.

### DETAILED DESCRIPTION

Example embodiments provide an output circuit and a light coupling device that drive a wide range of load capacitors with low power consumption.

In general, according to one embodiment, an output circuit for receiving an input signal and transmitting an output signal is provided. The output circuit includes an input terminal, an output terminal, a power supply terminal, a reference potential terminal, an output unit, a first drive circuit, and a second drive circuit. The output unit includes a first transistor of a first conductivity type including a drain and a source which are connected between the power supply terminal and the output terminal. The output unit further includes a first capacitance element connected between a gate and the drain of the first transistor. The output unit further includes a second transistor of a second conductivity type including a drain and a source which are connected between the reference potential and the output terminal. The output unit further includes a second capacitance element connected between a gate and the drain of the second transistor. The first drive circuit is configured to detect when the second transistor is turned off by a gate voltage of the second transistor, wherein the first drive circuit is configured to drive the first transistor to an on state. The second drive circuit is configured to detect when the first transistor is turned off by a gate voltage of the first transistor, wherein the second drive circuit is configured to drive the second transistor to an on state.

Hereinafter, embodiments according to the present disclosure will be described with reference to the drawings.

### First Embodiment

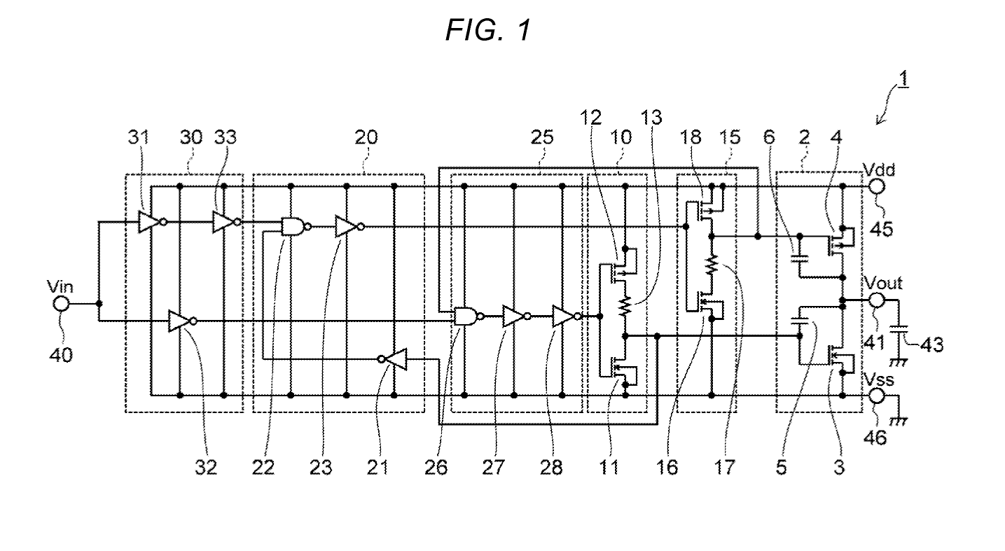

FIG. 1 is a circuit diagram illustrating a slew rate control output circuit according to a first embodiment.

As illustrated in FIG. 1, a slew rate control output circuit 1 includes an output unit 2, a low side transistor drive unit 10, a high side transistor drive unit 15, a low side monitoring unit 20, and a high side monitoring unit 25. The slew rate control output circuit 1 further includes an input terminal 40 to which an input signal Vin is input via an input unit 30, and an output terminal 41 from which a waveform of an output signal Vout having a slew rate controlled by the output unit 2 is output. The slew rate control output circuit 1 is connected between a power supply terminal 45 (e.g., at Vdd) and a ground terminal 46 (e.g., at Vss). The ground terminal 46 is a terminal that is connected to the lowest potential of the potentials to which the slew rate control output circuit 1 is connected, and is typically 0 V. The power supply terminal 45 is a terminal that is connected to the highest potential of the potentials to which the slew rate control output circuit 1 is connected, and is connected to, for example, 5 V.

The output unit 2 includes an N channel MOSFET 3 (second transistor) and a P channel MOSFET 4 (first transistor). Drain terminals of the N channel MOSFET 3 and the P channel MOSFET 4 are connected to each other. A source terminal of the N channel MOSFET 3 is connected to the ground terminal 46, and a source terminal of the P channel MOSFET 4 is connected to the power supply terminal 45. The output unit 2 that includes the N channel MOSFET 3 and the P channel MOSFET 4 forms an output circuit of a CMOS type. A capacitor 5 (second capacitor, also referred to as second capacitance element) is connected between a gate and a drain of the N channel MOSFET 3. A capacitor 6 (first capacitor, also referred to as first capacitance element) is connected between a gate and a drain of the P channel MOSFET 4. The capacitors 5 and 6 form mirror capacitors of the N channel MOSFET 3 and the P channel MOSFET 4, respectively, and determine a turn-on time and a turn-off time of the N channel MOSFET 3 and the P channel MOSFET 4, respectively. During a period in which the P channel MOSFET 4 turns on, the output signal Vout rises with a substantially constant slope. During a period in which the N channel MOSFET 3 turns on, the output signal Vout falls with a substantially constant slope. Thus, slew rates SRr and SRf at a rising time and a falling time respectively of the slew rate control output circuit 1 are substantially constant. In addition, since the N channel MOSFET 3 is connected to a low potential side with respect to the P channel MOSFET 4, the N channel MOSFET 3 may be also referred to as a low side transistor. Since the P channel MOSFET 4 is connected to a high potential side with respect to the N channel MOSFET 3, the P channel MOSFET 4 may be also referred to as a high side transistor.

The low side transistor drive unit 10 includes an N channel MOSFET 11 (sixth transistor), a P channel MOSFET 12 (fifth transistor), and a speed adjusting resistor 13 (second output resistor). The P channel MOSFET 12, the speed adjusting resistor 13, and the N channel MOSFET 11 are connected in series in this sequence between the power supply terminal 45 and the ground terminal 46. Anode that is between the speed adjusting resistor 13 and the N channel MOSFET 11 is connected to a gate terminal of the N channel MOSFET 3 in the output unit 2. Gate terminals of the N channel MOSFET 11 and the P channel MOSFET 12 are connected to each other, and are also connected to an output of the high side monitoring unit 25. The high side monitoring unit 25 and the low side transistor drive unit 10 are collectively an example of a second drive circuit. The low side transistor drive unit 10 drives the N channel MOSFET 3 of the output unit 2 in response to the output of the high side monitoring unit 25. Since the speed adjusting resistor 13 is in a current path that is formed when the N channel MOSFET 3 is turned on, a time required for turn-on of the N channel MOSFET 3 is longer than a turn-off time of the N channel MOSFET. The higher the resistance of the speed adjusting resistor 13, the longer before the N channel MOSFET 3 turns on (that is, the turn-on time is longer).

The high side transistor drive unit 15 includes an N channel MOSFET 16 (fourth transistor), a speed adjusting resistor 17 (first output resistor), and a P channel MOSFET 18 (third transistor). The P channel MOSFET 18, the speed adjusting resistor 17, and the N channel MOSFET 16 are connected in series in this sequence between the power supply terminal 45 and the ground terminal 46. A node that is between the P channel MOSFET 18 and the speed adjusting resistor 17 is connected to a gate terminal of the P channel MOSFET 4 in the output unit 2. Gate terminals of the N channel MOSFET 16 and the P channel MOSFET 18 are connected to each other, and also are connected to an output of the low side monitoring unit 20. The high side transistor drive unit 15 and the low side monitoring unit 20 are collectively an example of a first drive circuit. The high side transistor drive unit 15 drives the P channel MOSFET 4 of the output unit 2 in response to the output of the low side monitoring unit 20. Since the speed adjusting resistor 17 is in a current path that is formed when the P channel MOSFET 4 is turned on, a time required for turn-on of the P channel MOSFET 4 is longer than a turn-off time. The higher a resistance of the speed adjusting resistor 17, the longer before the P channel MOSFET 4 turns on (that is, the turn-on time is longer).

In this way, in the slew rate control output circuit 1 according to the first embodiment, the N channel MOSFET 3 and the P channel MOSFET 4 that are a CMOS type in the output unit 2 are driven by the drive circuits differently from each other. In addition, in the slew rate control output circuit 1, a speed adjusting resistor (e.g., speed adjusting resistors 13, 17) is used to ensure that the turn-off time of a MOSFET thus driven is shorter than the turn-on time thereof in both the low side transistor drive unit 10 and the high side transistor drive unit 15.

The low side monitoring unit 20 includes inverters 21 and 23, and a NAND 22. The input signal Vin from the input terminal 40 is fed through inverters 31 and 33 of input unit 30 and then into the NAND 22. Furthermore, a gate voltage Vnga of the N channel MOSFET 3 is input to the NAND 22 via the inverter 21. An output of the NAND 22 is connected to the high side transistor drive unit 15 through the inverter 23, and drives the P channel MOSFET 4 in the output unit 2 via the high side transistor drive unit 15.

The high side monitoring unit 25 includes a NAND 26, and inverters 27 and 28. An inverted signal of the input signal Vin and a gate voltage Vpga of the P channel MOSFET 4 are input to the NAND 26. An inverter 32 inverts the input signal Vin. An output of the NAND 26 is connected to the low side transistor drive unit 10 via the two inverters 27 and 28, and drives the N channel MOSFET 3 in the output unit 2 via the low side transistor drive unit 10.

The NAND 22 of the low side monitoring unit 20 monitors when the gate voltage Vnga of the N channel MOSFET 3 goes to a low level. If it is determined that the gate voltage Vnga is in a low level, the NAND 22 drives the high side transistor drive unit 15 so as to output a signal that makes the P channel MOSFET 4 turn on. A threshold voltage at which the low side monitoring unit detects that the gate voltage Vnga is in a low level is, for example, (½)×power supply voltage.

The NAND 26 of the high side monitoring unit 25 monitors that the gate voltage Vpga of the P channel MOSFET 4 which is a high side transistor goes to a high level. If it is determined that the gate voltage Vpga is in a high level, the NAND 26 drives the low side transistor drive unit 10 so as to output a signal that makes the N channel MOSFET 3 turn on. A threshold voltage which detects that the gate voltage Vpga is in a high level is an input threshold voltage of the NAND 26, for example, (½)×power supply voltage.

In addition, the threshold voltages of a logic level generated by the NANDs 22 and 26 may be set by changing the threshold voltages of logic gates in the front and the rear of the NANDs 22 and 26, for example, inverters 23 and 27, or the like.

In this way, the turn-off of each of the N channel MOSFET 3 and the P channel MOSFET 4 is monitored by detecting the levels of the respective gate voltages Vnga and Vpga.

The input unit 30 distributes the input signal Vin that is input from the input terminal 40 to the low side transistor drive unit 10 and the high side transistor drive unit 15 that are described above, via inverters 31 and 32, respectively. The low side transistor drive unit 10 and the high side transistor drive unit 15 operate according to an inverted logic, and thus an inverter 33 is inserted into one of the distribution paths, shown here as an example in the path between inverter 31 and low side monitoring unit 20.

Next, an operation of the slew rate control output circuit 1 will be described.

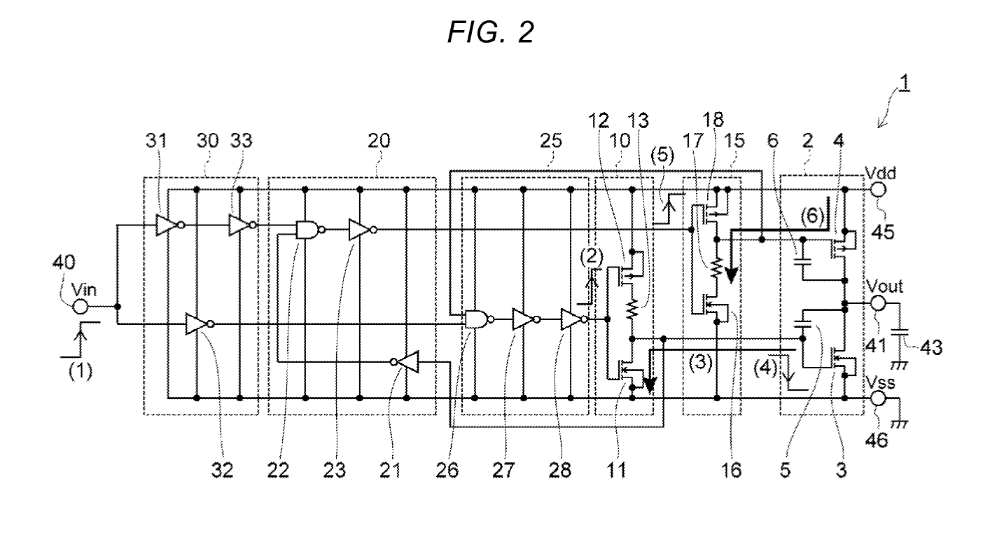

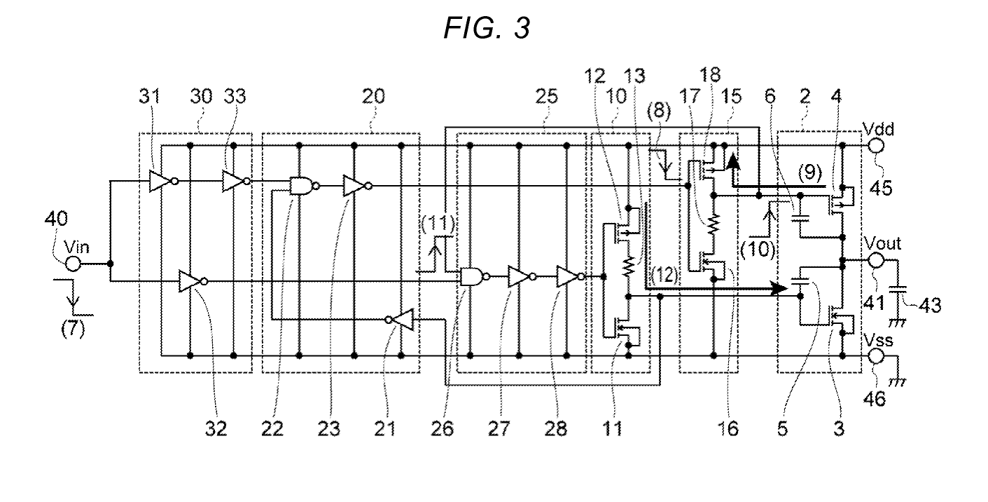

FIG. 2 and FIG. 3 illustrate sequences for performing operations with a substantially constant slew rate SRr and a substantially constant slew rate SRf when the output signal Vout, respectively, rises and falls.

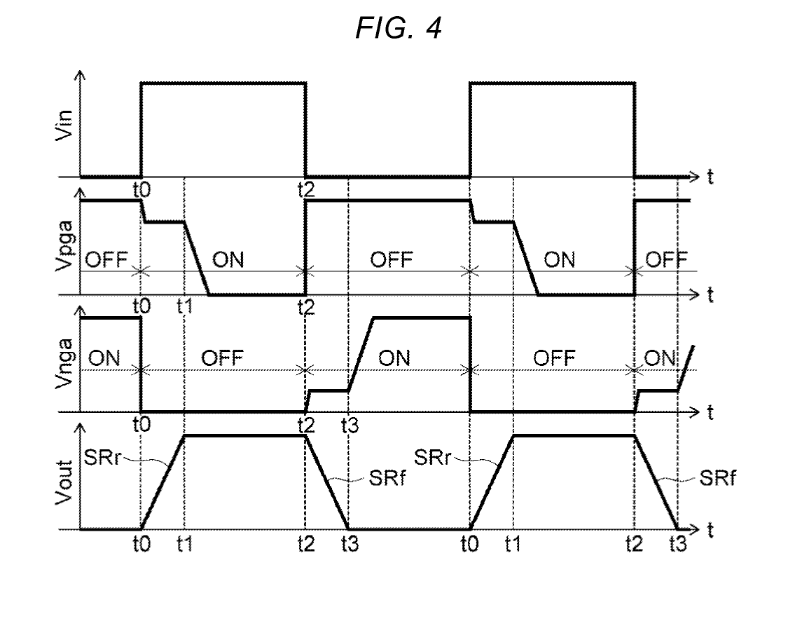

FIG. 4 schematically illustrates examples of simultaneous operation waveforms of the input signal Vin, the gate voltage Vpga of the P channel MOSFET 4, the gate voltage Vnga of the N channel MOSFET 3, and the output signal Vout, in the slew rate control output circuit 1 according to the first embodiment. A top waveform of FIG. 4 is an operation waveform of the input signal Vin that is input to the input terminal 40 of the slew rate control output circuit 1. In this example, the input signal Vin is a digital signal in which a low level is 0 V and a high level is 5 V. A second waveform from the top of FIG. 4 is an operation waveform of the gate voltage Vpga of the P channel MOSFET 4. A third waveform from the top of FIG. 4 is an operation waveform of the gate voltage Vnga of the N channel MOSFET 3. A bottom waveform of FIG. 4 is an operation waveform of the output signal Vout that is output from the output terminal 41.

Next, an operation sequence at the time of a rising output signal Vout will be first described.

As illustrated in FIG. 2 and FIG. 4, (1) if the input signal Vin is switched from a low level to a high level at input terminal 40 at time t0, then (2) a signal that is input to the low side transistor drive unit 10 is also transitioned from a low level to a high level. By this signal to the low side transistor drive unit 10 at (3) the N channel MOSFET 11 of the low side transistor drive unit 10 is turned on. Then at (4) the N channel MOSFET 11 of the low side transistor drive unit 10 begins to pull out the electric charges accumulated in a gate-source capacitor and a mirror capacitor 5 (hereinafter, simply referred to as gate capacitor) of the N channel MOSFET 3, whereby the N channel MOSFET 3 is turned off. At this time, the electric charges accumulated in the gate capacitor of the N channel MOSFET 3 are discharged via an ON resistance (the ON-state resistance of the transistor conductance pathway) of the N channel MOSFET 11 in the low side transistor drive unit 10, whereby the N channel MOSFET 3 is rapidly turned off.

Meanwhile at (5), the input signal Vin that is input from the input terminal 40 is input to the high side transistor drive unit 15 via the low side monitoring unit 20. The signal that is input to the high side transistor drive unit 15 is also transitioned from a low level to a high level at time t0. At (6) the N channel MOSFET 16 of the high side transistor drive unit 15 thus begins turning on charging a gate capacitor of the P channel MOSFET 4, and turning the P channel MOSFET 4 on. At this time, the gate capacitor of the P channel MOSFET 4 is charged via a conductance pathway including an ON resistance of the N channel MOSFET 16 and the speed adjusting resistor 17. A total resistance of the conductance pathway including the ON-state resistance of the N channel MOSFET 16 and the speed adjusting resistor 17 is set to be sufficiently higher (e.g., at least about five times higher, or at least about 15 times higher, or at least 30 times higher in some embodiments) than the resistance of the ON-state resistance of the N channel MOSFET 11 in the low side transistor drive unit 10.

A sequence from (1) to (4) corresponds to an operation by which the N channel MOSFET 3 turns on, and a sequence from (5) to (6) corresponds to an operation by which the P channel MOSFET 4 turns on. In this way, the low side monitoring unit 20 monitors the level of the gate voltage Vnga of the N channel MOSFET 3 to detect the turn-off of the N channel MOSFET 3. When the gate voltage Vnga is detected as a low level, the P channel MOSFET 4 turns on. Furthermore, if the N channel MOSFET 3 turns off, a resistance of an output resistor of the low side transistor drive unit 10 is set so as to be lower than an output resistor of the high side transistor drive unit 15 used to turn on the P channel MOSFET 4. Thus, the N channel MOSFET 3 rapidly turns off, and the P channel MOSFET 4 turns on after the N channel MOSFET 3 turns off.

In this way, it possible to prevent the N channel MOSFET 3 and the P channel MOSFET 4 from simultaneously turning on when the output signal Vout rises. In addition, logic gates of the NANDs 22 and 26 and the like, other transistors disposed within the circuit each have an intrinsic rising time, a falling time, or a propagation delay time. Consequently, there occurs a delay time from between the time the turn-off of the N channel MOSFET 3 is detected until the P channel MOSFET 4 turns on. Thus, a sequence at the time of rising of the output signal Vout includes a dead time period in which both of the N channel MOSFET 3 and the P channel MOSFET 4 are non-conducting.

Next, an operation sequence at the time of falling of the output signal Vout will be described.

As illustrated in FIG. 3 and FIG. 4, (7) if the input signal Vin is transitioned from a high level to a low level at time t2, (8) a signal that is input to the high side transistor drive unit 15 is also transitioned from a high level to a low level. By this signal, the P channel MOSFET 18 of the high side transistor drive unit 15 is turned on at (9), and the electric charges accumulated in the gate capacitor of the P channel MOSFET 4 are pulled out. Since the electric charges accumulated in the gate capacitor are pulled out at (10), the P channel MOSFET 4 will turn off. At this time, the electric charges accumulated in the gate capacitor of the P channel MOSFET 4 are discharged via the P channel MOSFET 18 in the high side transistor drive unit 15, whereby the P channel MOSFET 4 rapidly turns off.

Meanwhile at (11), the input signal Vin input at the input terminal 40 is input to the low side transistor drive unit 10 via the high side monitoring unit 25. The signal that is input to the low side transistor drive unit 10 is transitioned from a high level to a low level. At (12), the P channel MOSFET 12 of the low side transistor drive unit 10 turns on, whereby the gate capacitor of the N channel MOSFET 3 is charged, and the N channel MOSFET 3 turns on. At this time, the gate capacitor of the N channel MOSFET 3 is charged via a conduction pathway including the P channel MOSFET 12 and the speed adjusting resistor 13. A total resistance of the conductance pathway including the ON-resistance of the P channel MOSFET 12 and the speed adjusting resistor 13 is set to a sufficiently higher (e.g., at least about five times higher, or at least about 15 times higher, or at least 30 times higher in some embodiments) than that of an ON resistance of the P channel MOSFET 18 in the high side transistor drive unit 15.

A sequence from (7) to (10) corresponds to an operation by which the P channel MOSFET 4 turns off, and a sequence from (11) to (12) corresponds to an operation by which the N channel MOSFET 3 turns on. In this way, the high side monitoring unit 25 monitors the level of the gate voltage Vpga of the P channel MOSFET 4 and thereby detects the turn-off of the P channel MOSFET 4. When it is detected that the gate voltage Vpga goes to a high level, the N channel MOSFET 3 is turned on.

In this way, it possible to prevent the N channel MOSFET 3 and the P channel MOSFET 4 from simultaneously being in a conducting state when the output signal Vout falls. In addition, in the same manner as a case where the output signal Vout rises, due to a propagation delay time or the like of the logic gates and other circuit elements, there is a delay time between the detection of the turn-off of the P channel MOSFET 4 until the N channel MOSFET 3 turns on. Thus, even a sequence at the time of falling of the output signal Vout includes a dead time period in which both of the N channel MOSFET 3 and the P channel MOSFET 4 are non-conducting (turned off).

In the slew rate control output circuit 1 according to the first embodiment, a drive voltage to each of the gate terminal of the N channel MOSFET 3 and the gate terminal of the P channel MOSFET 4 is monitored to prevent the N channel MOSFET 3 and the P channel MOSFET 4 from simultaneously being in a conducting state (turned on). Since it is difficult here to be affected by switching noise or the like, as compared with a case where an operation state of an output unit is monitored by detecting the voltage at an output terminal, it is possible here to detect more accurately the turn-off timing of one MOSFET by monitoring the voltage at each gate terminal of the N channel MOSFET 3 and the P channel MOSFET 4. Consequently, it is possible to more consistently prevent the two MOSFETs in the output unit 2 from simultaneously being turned on, and thus to achieve lower power consumption. In addition, in the same manner as a case where the operation state of the output unit 2 is monitored by detecting the voltage at the output terminal 41, it is less necessary to control or compensate for the switching noise or the like in the output unit 2 of the first embodiment. For this reason, the slew rate control output circuit 1 does not require as complex of a circuit layout or as wide of signal wires, and nevertheless, it is possible to prevent the two MOSFETs (e.g., element 3 and element 4) in the output unit 2 from simultaneously turning on, whereby it is possible to achieve low power consumption.

Next, the setting of the slew rate SRr at the time of rising of the signal will be described.

If the gate capacitor of the P channel MOSFET 4 is referred to as Ciss(P), the mirror capacitor 6 is referred to as Cm(P), and a gate-source capacitor is referred to as Cgs(P), then Ciss(P) is represented as follows.

Ciss(P)=Cm(P)+Cgs(P)

If a gain of the P channel MOSFET 4 is referred to as A(P), Cm(P) is represented as follows.

Cm(P)=(1+A(P))·Cgr(P)

Thus,

Ciss(P)=(1+A(P))·Cgr(P)+Cgs(P) Formula (1)

For example, if a transistor with an appropriate size is considered by using a typical CMOS process using a design rule of 0.6 μm, then A(P)≈6 is satisfied. If an electrostatic capacitance value Cgr(P) of the mirror capacitor 6 that is connected between a gate and a drain of the P channel MOSFET 4 is set to 2 pF, and a parasitic capacitor Cgs between the gate and a source of the P channel MOSFET 4 is set to 1.2 pF, Ciss(P)=15.2 pF is satisfied by Formula (1).

If a charging current that charges the gate capacitor Ciss(P) of the P channel MOSFET 4 is referred to as Ich(P), the charging current Ich(P) is represented by the following formula.

Ich(P)≈Ciss(P)·dVout/dt

Here, if a desired SRr is set to, for example, a maximum of 5V/6 ns,

Ich(P)≈15.2 pF×5V/6 ns=12.7 mA

If a resistance value of the speed adjusting resistor 17 is set to 1 kΩ, Vdd/(Ron16+1 kΩ)≈5V/1 kΩ=5 mA is satisfied, and becomes a sufficiently smaller value than Ich(P). Thus, the current that passes through the speed adjusting resistor 17 may be considered to be a constant current.

In this way, a total resistance value of the ON resistance of the N channel MOSFET 16 and the speed adjusting resistor 17 is set to a sufficiently high value, and thus the gate capacitor Ciss(P) of the P channel MOSFET 4 is charged by a substantially constant current. During a period in which the gate capacitor Ciss(P) is being charged by a substantially constant current, the gate-source voltage Vpga of the P channel MOSFET 4 is a substantially constant voltage, and the output signal Vout as well as the drain-source voltage relative to the reference potential rises with a substantially constant slope as shown in FIG. 4.

A load capacitor (load capacitance) 43 is connected to the output terminal 41 of the slew rate control output circuit 1. Therefore, a relationship between the load capacitor 43 and the slew rate SRr will be reviewed. In the transistor that is designed by the typical CMOS process described above, the ON resistor (ON-resistance) Ron(P) of the N channel MOSFET 3 is generally about 50Ω. If an electrostatic capacitance value of the load capacitor 43 is referred to as CL and CL=10 pF, a time constant τ(P) is as follows:

τ(P)=Ron(P)·CL=50Ω×10 pF=0.5 ns.

The time constant τ(P) represents that 0.5 ns is required for an increase of (5 V×0.63)=3.15 V, whereby the slew rate is 3.15V/0.5 ns=6.3 V/ns. Meanwhile, a rising time based on the slew rate SRr obtained by a manner described above requires 6 ns for Vout to increase by 5 V, and thus SRr=5V/6 ns=0.48 V/ns. This is a long time, as compared with the time constant τ(P). Thus, if the load capacitor 43 is connected to the output terminal 41, the slew rate SRr is mostly determined by a time for the gate capacitor Ciss(P) of the P channel MOSFET 4 to be charged.

In this way, the rising time of the output unit 2 is determined by the gate capacitor Ciss(P) of the P channel MOSFET 4 and not by the load capacitor CL. The gate capacitor Ciss(P) value is mostly determined by the mirror capacitor corresponding to a gate-drain capacitor (capacitance). In addition, the gate capacitor Ciss(P) is charged by a constant current in output unit 2, and thus rising of the output signal Vout from the output unit 2 provides a substantially constant slew rate SRr.

As illustrated in FIG. 4, the slew rate SRr at the time of rising is determined by a period from the time t0 when the gate capacitor of the P channel MOSFET 4 in the output unit 2 starts to be charged until the time t1 when the charging is completed, and during this period, the slew rate SRr illustrates a substantially constant value. The slew rate SRr may be set by adjusting the total resistance value Ron(P) by altering the resistance value of the speed adjusting resistor 17 and/or the ON resistance of the N channel MOSFET 16 of the high side transistor drive unit 15 that configures a conductance path via which the gate capacitor Ciss(P) of the P channel MOSFET 4 is charged. The slew rate SRr may be set by adjusting the gate capacitor Ciss(P) of the P channel MOSFET 4 and/or by adjusting the summed resistance value Ron(P).

Next, the slew rate SRf at the time of falling is described in the same manner as the slew rate SRr at the time of rising. If the gate capacitor of the N channel MOSFET 3 is referred to as Ciss(N), the mirror capacitor 5 is referred to as Cm(N), and the gate-source capacitor is referred to as Cgs(N), Ciss(N) is represented by the following formula.

Ciss(N)=Cm(N)+Cgs(N)

If a gain of the N channel MOSFET 3 is referred to as A(N), Cm(N) is represented by the following formula.

Cm(N)=(1+A(N))·Cgr(N)

Ciss(N)=(1+A(N))·Cgr(N)+Cgs(N) Formula (2)

By charging the gate capacitor using a constant current, the output signal may fall at a substantially constant slew rate SRf, regardless of the load capacitor 43 (CL) that is connected to the output terminal 41.

In a case of the typical transistor that is produced using a 0.6 μm design rule in the same manner as the P channel transistor discussed above, A(N)≈7 is generally satisfied. If the electrostatic capacitance value Cgr(N) of the mirror capacitor 5 that is connected between the gate and the drain of the N channel MOSFET 3 is set to 1 pF, and the gate-source capacitor Cgs is set to 0.6 pF, Ciss(N)=8.6 pF is satisfied by Formula (2). Here, if a desired slew rate SRf is set to, for example, a maximum of 5V/6 ns in the same manner as the time of rising, the charging current Ich(N) is found as follows.

Ich(N)≈Ciss(N)·SRf=8.6 pF×5V/6 ns=7.2 mA

If the resistance value of the speed adjusting resistor 13 is set to, for example, 2 kΩ, then (Vdd/(Ron13+2 kΩ))≈5V/2 kΩ=2.5 mA is satisfied, and is a sufficiently smaller value than Ich(N). Thus, the current that passes through the speed adjusting resistor 13 may be considered to be a constant current.

In this way, in the same manner as described above where the output rises, a total resistance value of the ON resistance of the P channel MOSFET 12 and the speed adjusting resistor 13 is set so as to be sufficiently high, and thus it is possible to charge the gate capacitor Ciss(N) of the N channel MOSFET 3 using a constant current. Since the gate capacitor Ciss(N) of the N channel MOSFET 3 is charged by a constant current, the slew rate SRf at the time of falling of the output signal has a substantially constant value. The slew rate SRf may be set by adjusting the total resistance value of the speed adjusting resistor 13 and the ON resistance of the P channel MOSFET 12 of the low side transistor drive unit 10. The slew rate SRf may also be adjusted by changing the gate capacitor Ciss(N) of the N channel MOSFET 3 by adjusting the capacitance value of a gate-drain capacitor 5. The slew rate SRf may also be set by adjusting the gate capacitor together with an output resistance value of the low side transistor drive unit 10.

In this way, in the slew rate control output circuit 1 according to the first embodiment, it is possible to set the slew rates SRr and SRf at the time of rising and falling of the output signal Vout. By setting the input capacitors Ciss of the MOSFETs in the output unit 2 to be the same value as the load capacitor CL, it is possible to obtain the output signal Vout with a substantially constant slew rate regardless of the load capacitor CL. In addition, in the slew rate control output circuit 1 according to the first embodiment, it is possible to set the slew rates at the time of rising and at the time of falling to be equal to each other. Thus, it is possible to set the slew rate according to a parasitic inductance that is generated by a load connected to the output terminal 41, a length of the wire connected to the load, or the like, and to configure an interface circuit with higher versatility. In addition, in the slew rate control output circuit 1, in order to charge the gate capacitors Ciss of the MOSFETs in the output unit 2, resistor elements or ON resistances of the MOSFETs for driving are used in the charging conductance pathways, whereby it is possible to reduce power consumption more than that in a case where the constant current circuit is used to drive the output unit transistors. In the slew rate control output circuit 1, the low side monitoring unit 20 and the high side monitoring unit 25 detect the turn-off of one of the MOSFETs 3, 4 in the output unit 2 and then start the turn-on of the other MOSFET. Thus, the MOSFET that is turned on rises at a constant slew rate, whereby it is possible to substantially prevent the MOSFETs in the output unit 2 from simultaneously turning on. Thus, low power consumption is achieved in the slew rate control output circuit 1 according to the first embodiment.

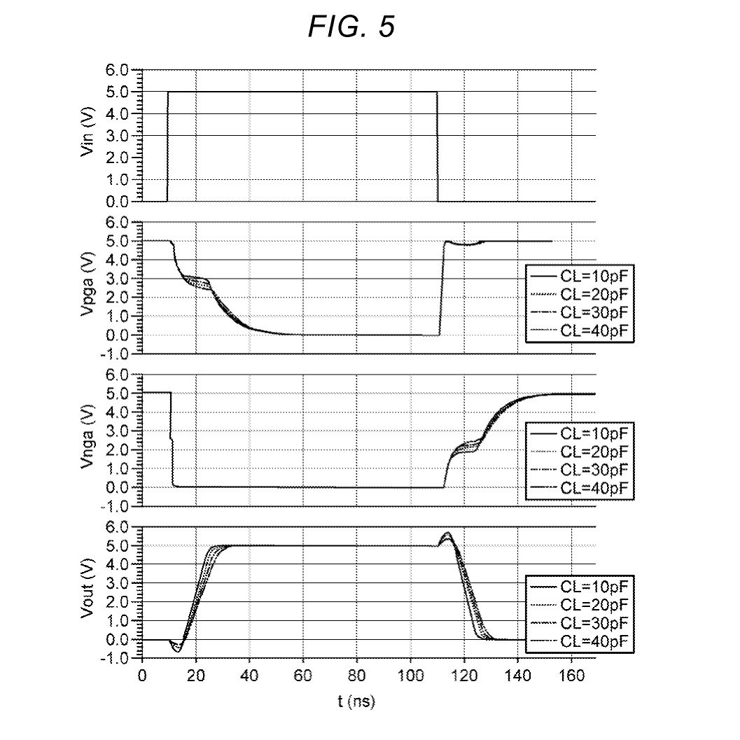

FIG. 5 illustrates operation waveforms where the capacitance value of the load capacitor 43 is changed by 10 pF increments from 10 pF to 40 pF, and illustrates operation waveforms when A(P)=6, Cgr(P)=2 pF, the resistance value of the speed adjusting resistor 13 is set to 1 kΩ, A(N)=7, Cgr(N)=1 pF, and the resistance value of the speed adjusting resistor 17 is set to 1 kΩ, by a manufacturing process using a typical 0.6 μm CMOS design rule that is used for the above-described calculation. The waveform diagrams from top to bottom in FIG. 5 correspond to the waveform diagrams from top to bottom in FIG. 4. As illustrated in the second and third waveform diagrams from top of FIG. 5, if the load capacitor 43 (CL) is changed, the voltage value of a flat portion indicating a mirror capacitor is changed, but there is no change in a time axis. For this reason, the slew rates SRr and SRf at the time of rising and falling of the output signal Vout have substantially constant values.

### Second Embodiment

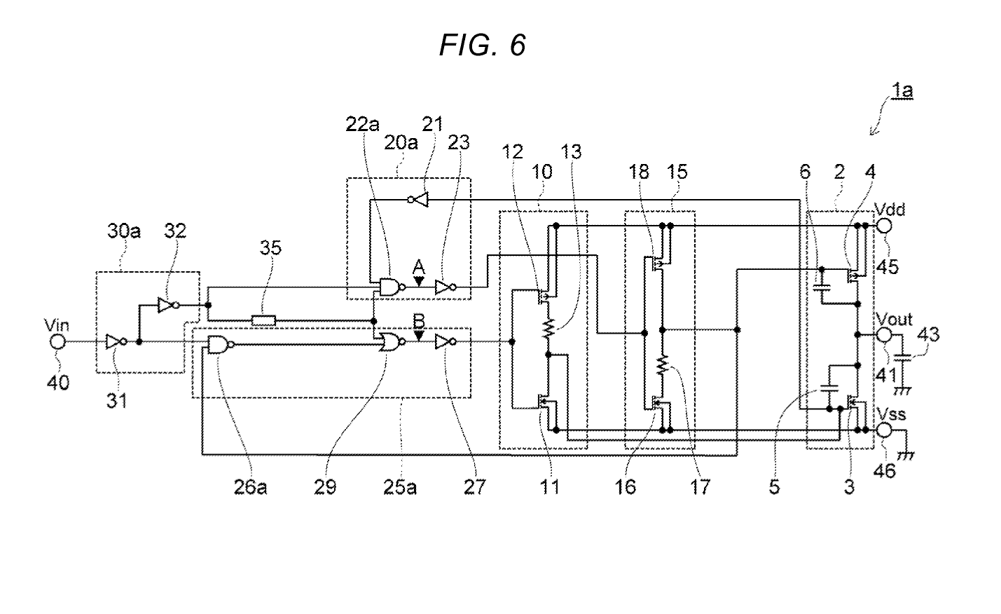

FIG. 6 is a circuit diagram illustrating a slew rate control output circuit according to a second embodiment.

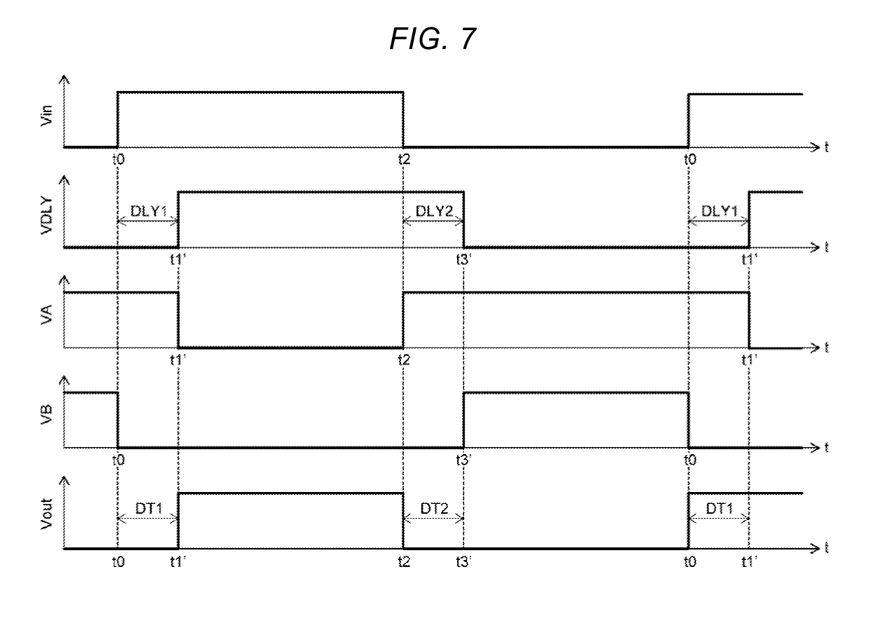

FIG. 7 is an operation waveform diagram for explaining an operation of the slew rate control output circuit of FIG. 6.

The slew rate control output circuit according to a second embodiment is different from the slew rate control output circuit according to the first embodiment, in that the slew rate control output circuit according to the second embodiment sets more specifically the dead timing (dead time) in which the N channel MOSFET 3 and the P channel MOSFET 4 in the output unit 2 are prevented from simultaneously turning on. Hereinafter, the same symbols or reference numerals as in the slew rate control output circuit 1 according to the first embodiment are attached to the same circuit elements and connections as in the slew rate control output circuit 1, and detailed description thereof will be omitted.

A slew rate control output circuit 1a according to the second embodiment includes the output unit 2, the low side transistor drive unit 10, the high side transistor drive unit 15, a low side monitoring unit 20a, a high side monitoring unit 25a, and an input unit 30a. The low side monitoring unit 20a, the high side monitoring unit 25a, and the input unit 30a are different from those of the slew rate control output circuit 1 according to the first embodiment, and the other units are substantially the same.

The low side monitoring unit 20a includes a NAND 22a with three inputs, and inverters 21 and 23. The gate voltage Vnga of the N channel MOSFET 3 in the output unit 2 is input to the first input of the three inputs of the NAND 22a. The input signal Vin is input to the second input of the NAND 22a. An output of a delay signal generation unit 35 is input to the third input of the NAND 22a.

The high side monitoring unit 25a includes a NAND 26a, a NOR 29 with two inputs, and an inverter 27. The input signal Vin, and the gate voltage Vpga of the P channel MOSFET 4 in the output unit 2 are input to the NAND 26a. One of the two inputs of the NOR 29 is connected to the output of the NAND 26a, and the other input of the NOR 29 is connected to the output of the delay signal generation unit 35.

The delay signal generation unit 35 is connected to the input signal Vin, and generates a signal waveform that is obtained by delaying the input signal Vin. The delay signal generation unit 35 may generate the same delay time at the times of rising and falling, and may generate different delay times from each other at the times of rising and falling. The delay signal generation unit 35 may be configured using an analog technology, such as a time constant circuit or a delay line that is configured with, for example a capacitor and a resistor, or a timer circuit, or may be configured using a digital technology such as a frequency divider. In addition, in the delay signal generation unit 35, an internal delay time may be fixed, or the delay time may be varied when connected to an external component, a variable power supply, or the like.

Referring to FIGS. 6 and 7, a dead time DT1 at the time of rising is set by a delay time DLY1 when the delay signal generation unit 35 rises. The dead time DT1 at the time of rising is defined as a period from the time when the P channel MOSFET 4 in the output unit 2 turns on to the time when the N channel MOSFET 3 starts to turn on. A dead time DT2 at the time of falling is defined as a period from the time when the N channel MOSFET 3 in the output unit 2 turns off to the time when the P channel MOSFET 4 starts to turn on.

In FIG. 7, in order to illustrate a sequence for generating the dead times, operation waveforms of voltages of each unit are schematically illustrated. A top waveform of FIG. 7 is an operation waveform of the input signal Vin. A second waveform from top of FIG. 7 is an operation waveform of a delay signal VDLY that is output from the delay signal generation unit 35. A third waveform from top of FIG. 7 is an operation waveform of the gate voltage Vpga of the P channel MOSFET 4 in the output unit 2, and illustrates that the P channel MOSFET 4 turns off when the gate voltage Vpga is in a high level, and the P channel MOSFET 4 turns on when the gate voltage Vpga is in a low level. A fourth waveform from top of FIG. 7 is an operation waveform of the gate voltage Vnga of the N channel MOSFET 3 in the output unit 2, and illustrates that the N channel MOSFET 3 turns on when the gate voltage Vnga is in a high level, and the N channel MOSFET 3 turns off when the gate voltage Vnga is in a low level. A bottom waveform of FIG. 7 is an operation waveform of the output signal Vout. In addition, since the operation waveforms of the gate voltages Vpga and Vnga of FIG. 7 illustrate a logic level only with a high level and a low level, waveforms of voltages VA and VB at labeled A point (illustrates a logic of Vpga) and labeled B point (illustrates a logic of Vnga) in FIG. 6 are illustrated. Hereinafter, in a case where operation waveforms are illustrated, unless particularly specified otherwise, the operation waveforms of the gate voltages Vpga and Vnga are waveforms of the voltages VA and VB illustrating logic levels of the gate voltages Vpga, Vnga, respectively.

As illustrated in FIG. 7, if the input signal Vin from the input terminal 40 is input to the delay signal generation unit 35, at time t0, the delay signal generation unit 35 detects rising of the input signal Vin, and outputs the delay signal VDLY that rises at time t1′.

The input signal Vin and the delay signal VDLY are respectively input to the NOR 29 of the high side monitoring unit 25a. The input signal Vin is input via the NAND 26a. The gate voltage Vpga of the P channel MOSFET 4 is input to the other input of the NAND 26a, whereby a signal with a high level from the NAND 26a is input to the NOR 29, at time t0. The NOR 29 outputs an inverted signal of a logical sum of the input signal Vin and the delay signal VDLY, thereby outputting a signal with a high level, at time t0. The low side monitoring unit 20a inverts the output of the NOR 29 via the inverter 27 making the N channel MOSFET 11 of the low side transistor drive unit 10 turn on, thereby making the gate voltage Vnga (VB) of the N channel MOSFET 3 in the output unit 2 go to a low level. The N channel MOSFET 3 in the output unit 2 starts to turn off at time t0.

The input signal Vin, the delay signal VDLY, and the gate voltage Vnga of the N channel MOSFET 3 are respectively input to the NAND 22a of the low side monitoring unit 20a. The low side monitoring unit 20a outputs an inverted signal of the logical product of the signals, whereby a logic level of the output of the low side monitoring unit 20a is inverted, at time t1′ when the delay signal VDLY changes state. For this reason, the high side transistor drive unit 15 makes the gate voltage Vpga of the P channel MOSFET 4 in the output unit 2 go to a low level, at time t1′, whereby the P channel MOSFET 4 is turned on.

In this way, at time t0 when the input signal Vin rises, the N channel MOSFET 3 in the output unit 2 turns off, and at time t1′ after the delay time DLY1 passes, the P channel MOSFET 4 turns on. Thus, when the input signal Vin rises, the output signal Vout includes substantially the same dead time DT1 as the delay time DLY1.

If the delay signal generation unit 35 detects falling of the input signal Vin (e.g., at time t2), the delay signal VDLY is output as a signal with a high level. The input signal Vin, the delay signal VDLY, and the gate voltage Vnga of the N channel MOSFET 3 in output unit 2 are respectively input to the NAND 22a of the low side monitoring unit 20a. The low side monitoring unit 20a outputs the logical product of the signals, whereby at time t2, a logic level of the output of the low side monitoring unit 20a is inverted. For this reason, the high side transistor drive unit 15 makes the gate voltage Vpga of the P channel MOSFET 4 in the output unit 2 go to a high level at time t2, whereby the P channel MOSFET 4 turns off.

The input signal Vin and the delay signal VDLY are respectively input to the NOR 29 of the high side monitoring unit 25a. The input signal Vin is input via the NAND 26a, and at time t2, the input signal Vin is inverted to signal with a low level, whereby the output of the NAND 26a is a high level due to the voltage Vpga of the P channel MOSFET 4. The NOR 29 outputs an inverted signal of the logical sum of the output of the NAND 26a and the delay signal VDLY, whereby at time t2, a signal with a low level is output from the NOR 29. The low side monitoring unit 20a inverts the output of the NOR 29 via the inverter 27, and thus makes the N channel MOSFET 11 of the low side transistor drive unit 10 turn on, thereby maintaining the gate voltage Vnga of the N channel MOSFET 3 in the output unit 2 at a low level. At time t2, both of the P channel MOSFET 4 and the N channel MOSFET 3 in the output unit 2 are at an off state. Thereafter, at time t3′, the delay signal generation unit 35 inverts the output (VDLY) into a signal with a low level. For this reason, the output of the NOR 29 in the high side monitoring unit 25a changes state to a high level. The high level from the NOR 29 is then inverted to a low level through the inverter 27. The low side transistor drive unit 10 then receives the output of the high side monitoring unit 25a, makes the gate voltage Vnga of the N channel MOSFET 3 in the output unit 2 go to a high level, whereby the N channel MOSFET 3 turns on. Thereby, the output signal Vout is transitioned from a high level to a low level.

In this way, in the slew rate control output circuit 1a according to the second embodiment, the delay signal generation unit 35 is added in association with the input signal Vin, and thus it is easy to generate the dead time, and thus in an operation in a range from a low frequency to a high frequency, it is possible to prevent the MOSFETs in the output unit 2 from simultaneously turning on, whereby it is possible to reduce power consumption.

In addition, a configuration of a logic circuit for generating the dead time at the times of rising and falling of the input signal Vin, is not limited to the above description, and it is possible to perform various modification, such as to input the output signal VDLY of the delay signal generation unit to the NAND of the high side monitoring unit.

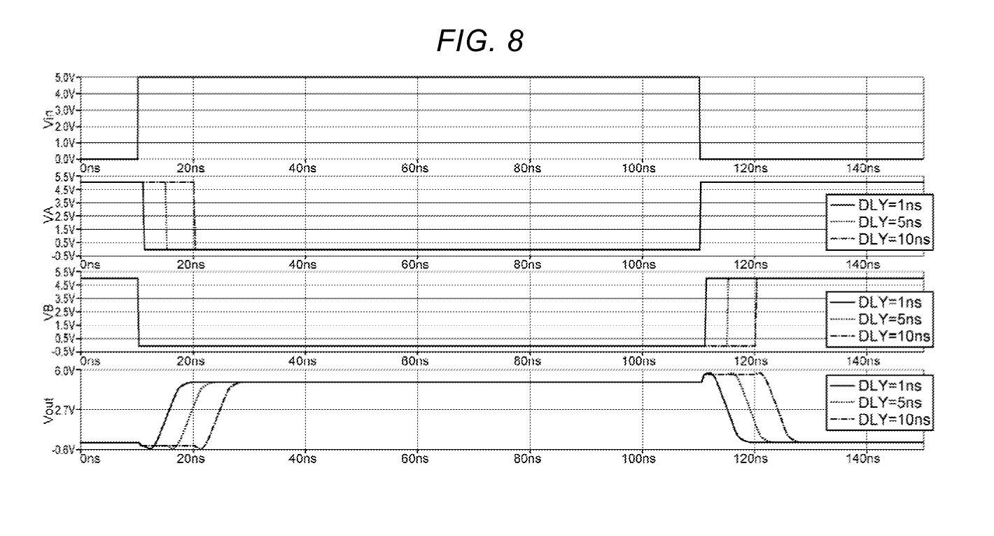

FIG. 8 to FIG. 11 are operation waveform diagrams illustrating an operation state of the slew rate control output circuit of FIG. 6.

FIG. 8 illustrates the effect on the output signal Vout in a case where delay times DLY1 and DLY2 of the slew rate control output circuit 1a of FIG. 6 are changed. A top waveform of FIG. 8 is an operation waveform of the input signal Vin. A second waveform from top of FIG. 8 is an operation waveform of the logic level VA of the gate voltage Vpga of the P channel MOSFET 4 in the output unit 2. A third waveform from top of FIG. 8 is an operation waveform of the logic level VB of the gate voltage Vnga of the N channel MOSFET 3 in the output unit 2. A bottom waveform of FIG. 8 is an operation waveform of the output signal Vout. In the example of FIG. 8, the delay times are set in such a manner that DLY1, DLY2, and DLY discussed above are all equal for a given configuration (e.g., DLY1, DLY2, DLY are all 1 ns for one configuration, all 5 ns for another configuration, and all 10 ns for another configuration). In the second waveform to the bottom waveform, solid lines illustrate a case where DLY=1 ns, dashed lines illustrate a case where DLY=5 ns, and alternate long and short dash lines illustrate a case where DLY=10 ns. As illustrated in FIG. 8, the dead time DT that is substantially the same as the delay times DLY which are set to each of the time of rising and the time of falling, is generated, and the slew rate of the output signal Vout is constant even if the dead time is changed.

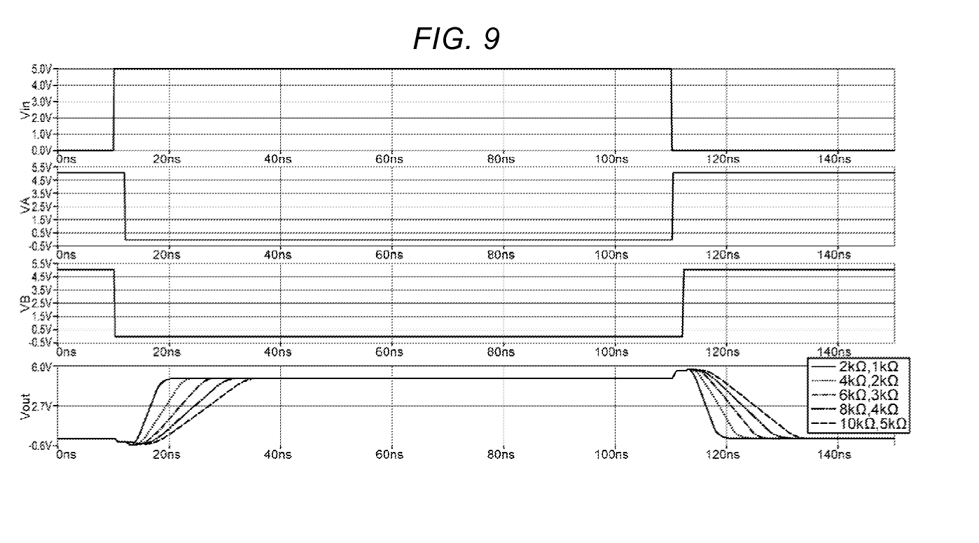

FIG. 9 is an example of operation waveforms in a case where the slew rates SRr and SRf at the times of rising and falling are changed, in the slew rate control output circuit 1a of FIG. 6. In order to change the slew rates SRr and SRf, the speed adjusting resistor 13 of the low side transistor drive unit 10 and the speed adjusting resistor 17 of the high side transistor drive unit 15 are changed. Resistance values of the speed adjusting resistors 13 and 17 in a case of obtaining waveforms of solid line are set to 2 kΩ and 1 kΩ, respectively, the resistance values in a case of obtaining waveforms of dotted line are set to 4 kΩ and 2 kΩ, respectively, the resistance values in a case of obtaining waveforms of alternate long and short dash line are set to 6 kΩ and 3 kΩ, respectively, the resistance values in a case of obtaining waveforms of two-dot chain line are set to 8 kΩ and 4 kΩ, respectively, and the resistance values in a case of obtaining waveforms of dashed line are set to 10 kΩ and 5 kΩ, respectively.

In this way, by changing the speed adjusting resistors 13 and 17, the slew rates SRr and SRf may be changed. In addition, it is possible to separately set the turn-on conditions of the P channel MOSFET 4 and the N channel MOSFET 3 in the output unit 2, using the speed adjusting resistors 13 and 17, and to configure an output circuit with more general versatility.

As described above, the slew rates SRr and SRf of the slew rate control output circuit 1a are also determined by the time required for the gate capacitors of the MOSFETs in the output unit 2 to be charged. In some embodiments, since the current that charges the gate capacitors is mostly determined by output resistors of the low side transistor drive unit 10 and the high side transistor drive unit 15, it is possible to change the slew rates SRr and SRf by respectively adjusting the ON resistance of the P channel MOSFET 12 of the low side transistor drive unit and the ON resistance of the N channel MOSFET 16 of the high side transistor drive unit 15, instead of specifically inserting the speed adjusting resistors 13 and 17.

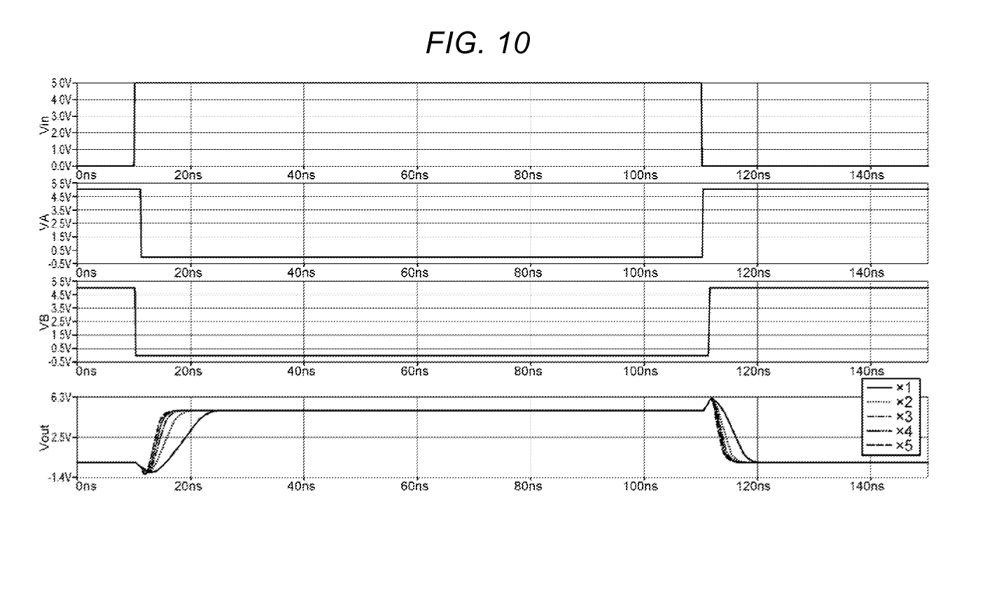

FIG. 10 is an example of operation waveforms in a case of setting the slew rates SRr and SRf by changing transistor sizes of the P channel MOSFET 12 and the N channel MOSFET 16. A top waveform to a bottom waveform of FIG. 10 correspond to the top waveform to the bottom waveform of FIG. 8. The transistor sizes of the P channel MOSFET 12 and the N channel MOSFET 16 in a case of obtaining the waveforms of solid line are respectively set to 1, the transistor sizes in a case of obtaining the waveforms of dotted line are respectively set to 2, the transistor sizes in a case of obtaining the waveforms of alternate long and short dash line are respectively set to 3, the transistor sizes in a case of obtaining the waveforms of two-dot chain line are respectively set to 4, and the transistor sizes in a case of obtaining the waveforms of dashed line are respectively set to 5. In addition, the transistor sizes are set to the same values, even at the times of rising and falling. The transistor size is W/L. Here, W is a gate width, L is a gate length, and the change of the above-described transistor size is performed by substantially changing W.

In this way, the transistor sizes are changed without using the speed adjusting resistors, and it is possible to easily set the slew rates by adjusting the ON resistances of the MOSFETs in the drive units.

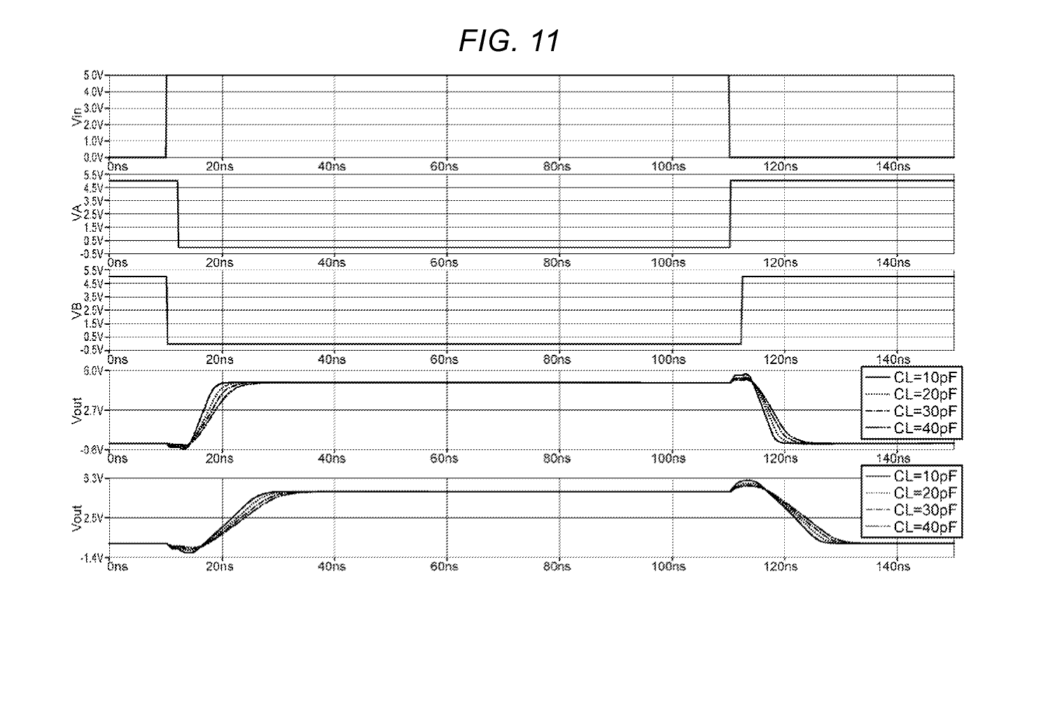

FIG. 11 is an example of operation waveforms illustrating the effect on the output signal Vout from changing the electrostatic capacitance value of the load capacitor that is connected to the output terminal 41. A top waveform to a fourth waveform from top of FIG. 11 correspond to the top waveform to bottom waveform of FIG. 8. The bottom waveform of FIG. 11 illustrates an operation waveform of the output signal Vout in a case of largely setting the electrostatic capacitance values of the gate-drain capacitors of the N channel MOSFET 3 and the P channel MOSFET 4 in the output unit 2 to 3 pF and 6 pF, respectively. All the waveforms illustrate a case where a solid line is CL=10 pF, a case where a dashed line is CL=20 pF, a case where an alternate long and short dash line is CL=30 pF, and a case where a two-dot chain line is CL=40 pF.

The capacitors 5 and 6 are connected between the gates and drains of the MOSFETs in the output unit 2. By setting a capacitance value in which a mirror effect is considered as well as the maximum load capacitance value, it is possible to obtain a stable operation waveform. The slew rate is little changed, even if a load capacitor with a smaller capacitance value than that which is driven is used. By setting the electrostatic capacitance values of the capacitors 5 and 6 to sufficiently high values, the slew rates SRr and SRf may be relatively little affected by the specific capacitance value CL of the load capacitor 43 that is connected to the output terminal 41 or some range of load capacitance values.

In addition, in FIG. 9 and FIG. 11 that are described above, a case of the slew rate control output circuit 1a according to the second embodiment is described, but it is apparent that a case of the slew rate control output circuit 1 according to the first embodiment also obtains a similar result.

### Third Embodiment

In the above-described slew rate control output circuits 1 and 1a, the turn-on times of the MOSFETs in the output unit 2 are controlled and the slew rates are set by drive capacities that are determined by the speed adjusting resistors 13 and 17 or the like. Since the speed adjusting resistors 13 and 17 or the like are connected between the power supply voltage and the ground, drive capacities thereof are affected by the change of the power supply voltage. If the power supply voltage significantly decreases, the charging current that charges the gate capacitors of the MOSFETs that is output from the speed adjusting resistors 13 and 17 or the like significantly decreases. For this reason, the slew rate is significantly decreased. If the slew rate of the output signal Vout is decreased, the output signal Vout with a desired operation frequency is output, but the load cannot be driven. Thus, it is preferred to monitor the power supply voltage.

A slew rate control output circuit 1b according to the third embodiment includes a low voltage protection unit 50 and a NAND 60 that are added to the slew rate control output circuit 1a according to the second embodiment. Hereinafter, the same symbols or reference numerals as in the slew rate control output circuit 1a according to the second embodiment are attached to the same circuit elements and connections as in the slew rate control output circuit 1a, and detailed description thereof will be omitted.

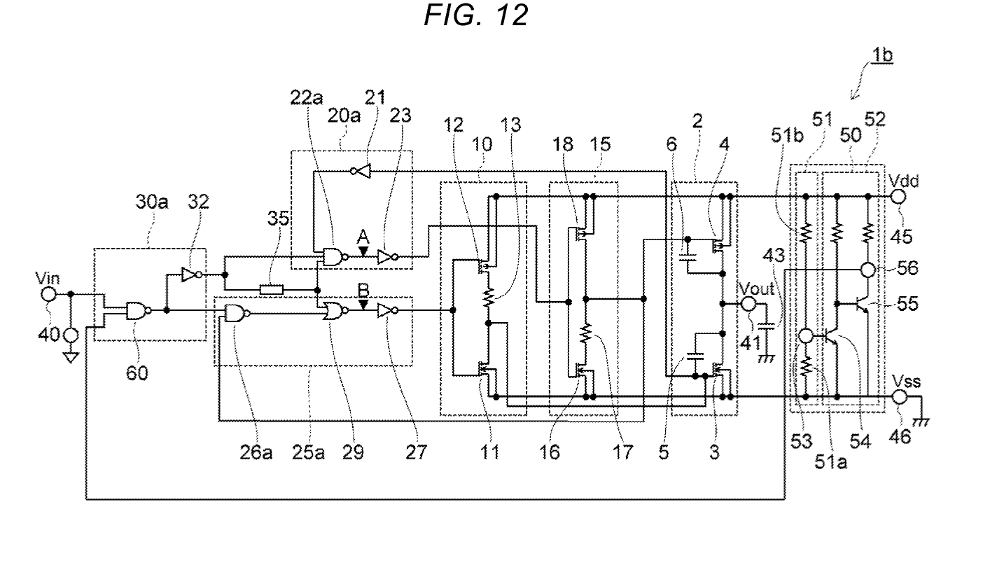

As illustrated in FIG. 12, the slew rate control output circuit 1b according to the third embodiment further includes the low voltage protection unit 50 and the NAND 60. The low voltage protection unit 50 includes a voltage detection unit 51 that detects the power supply voltage, and a comparator 52 that compares the detected power supply voltage with a threshold voltage which is set in advance, and outputs the comparison result. The voltage detection unit 51 is configured with two resistors 51a and 51b that are connected in series to each other. The comparator 52 includes an input terminal 53, an input transistor 54, an inverting transistor 55, and a first output terminal 56. The input transistor 54 and the inverting transistor 55 configure an inverter circuit that uses a resistor as a load. The input transistor 54 includes abase terminal that is connected to an input terminal 53 of the comparator 52, and the input terminal 53 is connected to a connection point of two resistors 51a and 51b in the voltage detection unit 51. The threshold voltage is an on voltage, for example, 0.6 V between a base and an emitter of the input transistor 54. The inverting transistor 55 includes a base terminal that is connected to a collector terminal of the input transistor 54. A collector terminal of the inverting transistor 55 is connected to a first output terminal 56 of the comparator 52. The first output terminal 56 of the comparator is connected to one input of the NAND 60. The input signal Vin is input to the other input of the NAND 60.

If the power supply potential is within a normal operation range, a potential at the input terminal 53 of the comparator 52 is a voltage equal to or higher than an ON voltage of the base-emitter voltage of the input transistor 54, and the input transistor 54 is in an ON state. For this reason, a base-emitter voltage of the inverting transistor 55 is equal to or lower than the ON voltage of the input transistor 54, and the inverting transistor 55 is in an OFF state. For this reason, the first output terminal 56 of the comparator 52 outputs a signal with a high level, and the NAND 60 outputs a signal according to the input signal Vin.

Meanwhile, if the power supply voltage decreases, whereby a voltage at the input terminal 53 of the comparator 52 decreases to a voltage lower than an ON voltage between a base and an emitter of the input transistor 54, the input transistor 54 turns off. A base-emitter voltage of the inverting transistor 55 increases to an ON voltage, whereby the inverting transistor 55 turns on. For this reason, one input of the NAND 60 goes to a low level, whereby the NAND 60 outputs a signal with a high level, regardless of the input signal Vin. Then, the P channel MOSFET 4 in the output unit 2 turns off, and the N channel MOSFET 3 maintains in an ON state.

In addition, it is preferable that the low voltage protection unit 50 be configured with a bipolar transistor or a MOS transistor with a low threshold voltage, in order to ensure that the low voltage protection unit 50 operates at a lower voltage than a voltage which limits the operation of another unit in the slew rate control circuit 1b.

In this way, in the slew rate control output circuit 1b according to the third embodiment, if the power supply voltage decreases, the level of the output signal Vout is maintained in a low level, regardless of the input signal Vin.

### Fourth Embodiment

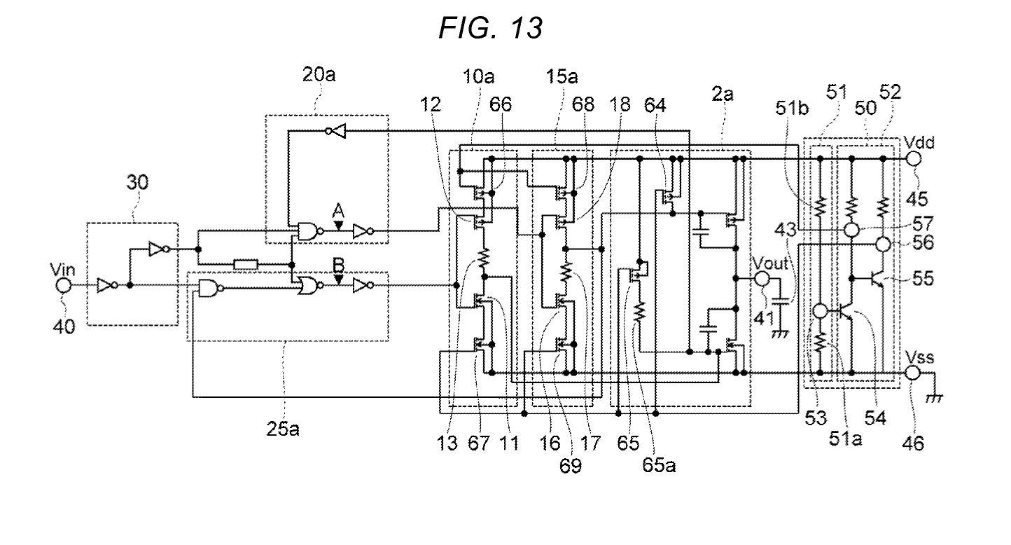

FIG. 13 is a circuit diagram illustrating a slew rate control output circuit according to a fourth embodiment.

In the slew rate control output circuit 1b according to the third embodiment, since the operation of the subsequent logic circuit can be disabled using the NAND 60 disposed in the input unit 30a, the operation up to the low voltage operation limit of the NAND circuit 60 on the input side is ensured. The NAND circuit can include the configuration of an input circuit in which two MOSFETs are connected in series to each other. In such a configuration, a power supply voltage that is more than two times a threshold voltage for turning on or off a transistor is required in order to ensure the operation of the NAND circuit. In order to ensure an operation of a remainder of the light receiving circuit at a lower power supply voltage, it is necessary to add some additional switches as discussed below.

The slew rate control output circuit according to the fourth embodiment further includes the low voltage protection unit 50, gate switches 64 and 65, low side transistor drive unit blocking switches 66 and 67, and high side transistor drive unit blocking switches 68 and 69. Hereinafter, the same symbols or reference numerals as in the slew rate control output circuit 1b according to the third embodiment are attached to the same circuit elements and connections as in the slew rate control output circuit 1b, and detailed description thereof will be omitted.

The low voltage protection unit 50 is substantially the same as that of the slew rate control output circuit 1b according to the third embodiment. The low voltage protection unit 50 according to the fourth embodiment includes a second output terminal 57. The second output terminal 57 is connected to the collector terminal of the input transistor 54.

The gate switch 64 is connected between the gate and the source of the P channel MOSFET 4 in the output unit 2. The gate switch 65 is connected in series to a resistor 65a, between the gate of the N channel MOSFET 3 in the output unit 2 and the power supply terminal 45. Gate terminals of the gate switches 64 and 65 are each connected to the first output terminal 56 of the comparator 52.

The low side transistor drive unit blocking switch 66 is connected between the power supply terminal 45 and the P channel MOSFET 12 of the low side transistor drive unit 10a. The low side transistor drive unit blocking switch 67 is connected between the N channel MOSFET 11 of the low side transistor drive unit 10a and the ground terminal 46. Gate terminals of the low side transistor drive unit blocking switches 66 and 67 are connected to the second output terminal 57 and the first output terminal 56 of the comparator 52, respectively.

The high side transistor drive unit blocking switch 68 is connected between the power supply terminal 45 and the P channel MOSFET 18 of the high side transistor drive unit 15a. The high side transistor drive unit blocking switch 69 is connected between the N channel MOSFET 16 of the high side transistor drive unit 15a and the ground terminal 46. Gate terminals of the high side transistor drive unit blocking switches 68 and 69 are connected to the second output terminal 57 and the first output terminal 56 of the comparator 52, respectively.

If the potential at the power supply terminal 45 is within a normal operation voltage range, a potential at the input terminal 53 of the comparator 52 is a voltage equal to or higher than an ON voltage of the base-emitter voltage of the input transistor 54, and the input transistor 54 is in an ON state. A base-emitter voltage of the inverting transistor 55 is equal to or lower than the ON voltage, and the inverting transistor 55 is in an OFF state. As a result, the first output terminal 56 of the comparator 52 outputs a signal with a high level, and the second output terminal 57 outputs a signal with a low level.

The gate switches 64 and 65 are both turned off by the high level from the first output terminal 56. Thus, the P channel MOSFET 4 and the N channel MOSFET 3 in the output unit 2 are in an enable state. The low side transistor drive unit blocking switches 66 and 67, and the high side transistor drive unit blocking switches 68 and 69 are all turned on by the outputs of the first output terminal 56 and the second output terminal 57. Thus, the low side transistor drive unit 10a and the high side transistor drive unit 15a are both in an enable state.

Meanwhile, if the power supply voltage decreases whereby a voltage at the input terminal 53 of the comparator 52 decreases to a voltage lower than an ON voltage between a base and an emitter of the input transistor 54, the input transistor turns off. A base-emitter voltage of the inverting transistor 55 increases to an ON voltage, whereby the inverting transistor 55 turns on. The first output terminal 56 of the comparator 52 outputs a signal with a low level, and the second output terminal 57 outputs a signal with a high level. The gate switches 64 and 65 are both turned on by the outputs of the first output terminal 56. Thus, the P channel MOSFET 4 in the output unit 2 turns off, and the N channel MOSFET 3 in the output unit 2 turns on. Thus, the output terminal 41 is maintained in a low impedance state. The low side transistor drive unit blocking switches 66 and 67, and the high side transistor drive unit blocking switches 68 and 69 are all turned off by the outputs of the first output terminal 56 and the second output terminal 57. Thus, the low side transistor drive unit 10a and the high side transistor drive unit 15a both enter a disabled operation state that is disconnected from the power supply.

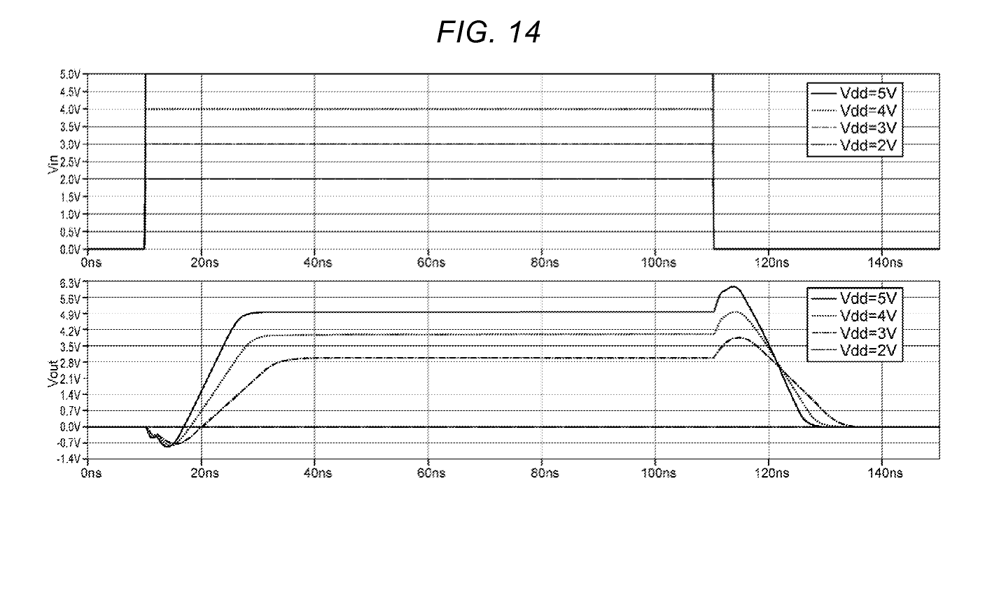

In FIG. 14, an upper graph is a diagram illustrating examples of an operation waveform of the input signal Vin, and a lower graph is a diagram illustrating examples of an operation waveform of the output signal Vout. Both illustrate waveforms using in common time axes. The waveform of a solid line is formed when the power supply voltage is 5 V, the waveform of a dashed line is formed when the power supply voltage is 4 V, the waveform of an alternate long and short dash line is formed when the power supply voltage is 3 V, and the waveform of a two-dot chain line is formed when the power supply voltage is 2 V.

In a range that the power supply voltage is 3 V to 5V, the output signal Vout is normally output. However, as the power supply decreases, the slew rates SRr and SRf also decrease. If the power supply voltage decreases to 2 V, the output signal Vout is fixed to a low level by the function of the low voltage protection unit 50.

The slew rate control output circuit according to the present embodiment controls ON and OFF of one MOSFET without using a NAND, thereby switching enablement and disablement of a circuit, and thus an operation is ensured down to a lower voltage than that of the slew rate control output circuit 1b according to the third embodiment.

### Fifth Embodiment

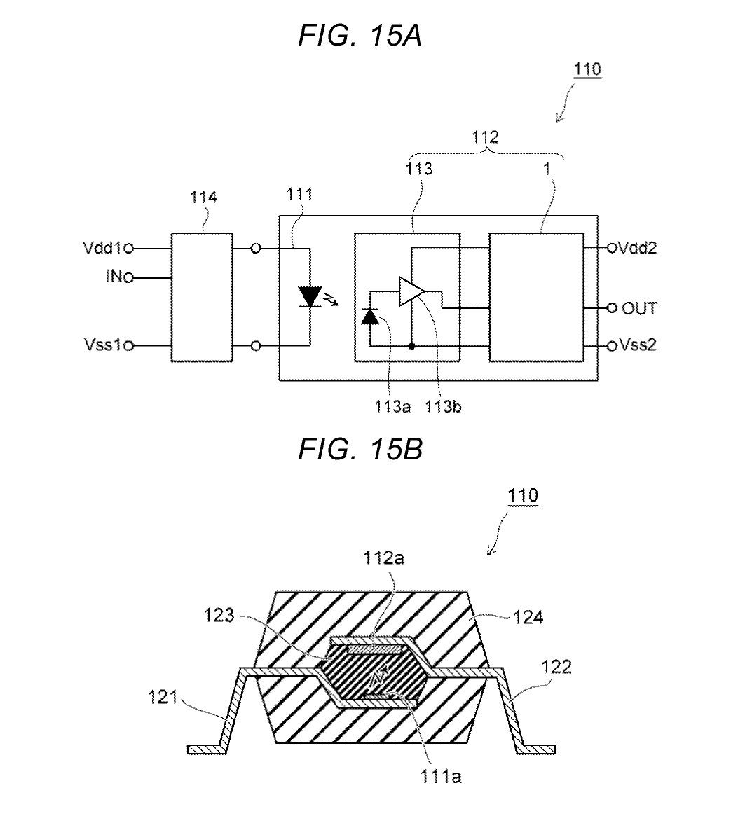

FIG. 15A is a block diagram illustrating a light coupling device according to a fifth embodiment. FIG. 15B is a cross-sectional view illustrating a structure of the light coupling device according to the fifth embodiment.

The light receiving circuits are used together with a light transmitting circuit that transmits a light signal, and may be used for a light coupling device 110. The light coupling device 110 is used in circumstances where it may be difficult to transmit a signal with a direct connection of an electric circuit or the like because a voltage level is significantly different between an input and an output. The light coupling device 110 is, for example, a photocoupler.

As illustrated in FIG. 15A, the light coupling device 110 according to the fifth embodiment includes a light emitting element 111 and a receiving circuit 112.

The light emitting element 111 is an infrared emitting diode including, for example, AlGaAs or the like. The light emitting element 111 is driven by a drive circuit 114. The drive circuit 114 is connected to an external power supply that outputs, for example, voltage Vdd1 or Vss1, and a signal is input from a signal input terminal IN. The light emitting element 111 emits light according to an input signal, and transmits a light signal to a light receiving circuit 113. Vdd1 is, for example, +5 V, and Vss1 is, for example, −5 V.

The receiving circuit 112 includes the light receiving circuit 113 and the slew rate control output circuit 1. The slew rate control output circuit is not limited to the slew rate control output circuit 1 according to the first embodiment, and may be, of course, a slew rate control output circuit according to another embodiment. The light receiving circuit 113 includes a light receiving element 113a, and a trans-impedance amplifier 113b that converts a light current output from the light receiving element 113a into a voltage signal. The light receiving circuit 113 converts an analog signal to a digital signal, and inputs the digital signal to the slew rate control output circuit 1. The slew rate control output circuit 1 transmits the digital signal to a digital signal processing circuit or the like (not illustrated) via a cable or the like. It is preferable that the light receiving circuit 113 and the slew rate control output circuit 1 operate using a common power supply, but may use a separate power supply for the slew rate control output circuit 1 in order to drive the load capacitor(s). When a single power supply is used, an operation voltage is Vdd2-Vss2, where Vdd2 is, for example, 5 V, and Vss2 is, for example, 0 V.

As illustrated in FIG. 15B, the light coupling device 110 includes a lead frame 121 on which a light emitting element chip 111a including the light emitting element 111 formed on a semiconductor substrate thereof is mounted and which is connected to the light emitting element chip 111a by bonding wires (not specifically illustrated), and a lead frame 122 on which a receiving circuit chip 112a having the receiving circuit 112 formed on a semiconductor substrate thereof is mounted and which is connected to the receiving circuit chip 112a by bonding wires (not specifically illustrated). The lead frames 121 and 122 are disposed so that surfaces on which the light emitting element chip 111a and the receiving circuit chip 112a are mounted face each other. Portions of the light emitting element chip 111a and the receiving circuit chip 112a that are disposed to face each other are covered with a transparent resin 123 in consideration of light transmission loss. Furthermore, outer circumference portions thereof are sealed with an epoxy-based light-shielding resin 124 by using, for example, a transfer mold technology. The light coupling device 110 is electrically connected to the drive circuit 114 using leads of the lead frame 121 on which the light emitting element chip 111a is mounted, and obtains output signals from leads of the lead frame 122 on which the receiving circuit chip 112a is mounted.

Since the light coupling device 110 includes the slew rate control output circuit 1 that outputs an output signal which is controlled to a constant slew rate, it is possible for the light coupling device 110 to be connected to a load circuit having a wide range of capacitors, and to drive the load circuit so as to have low noise and low power consumption.

### Sixth Embodiment

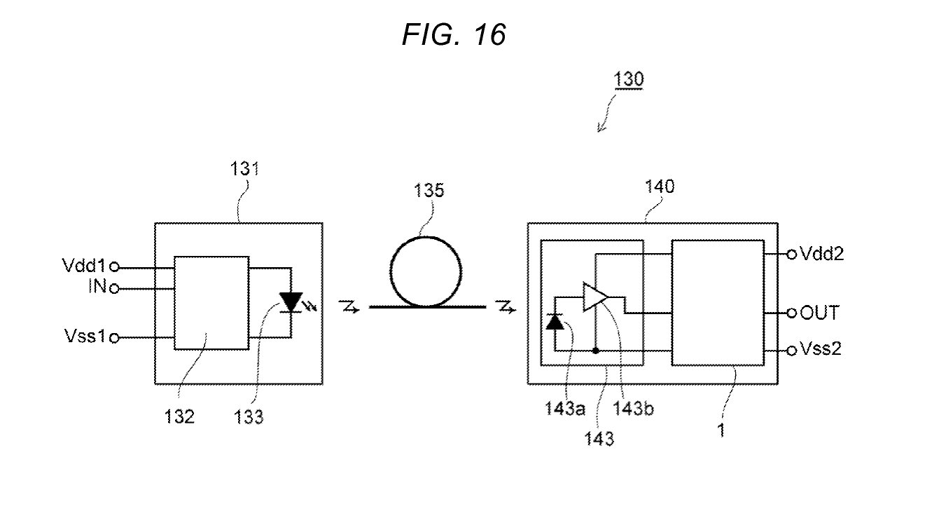

FIG. 16 is a block diagram illustrating a light communication system according to a sixth embodiment.

The slew rate control output circuit 1 according to the embodiment described above is used in a receiving device 140 together with a transmission device 131 that transmits a light signal, and may be used in a light communication system 130. The receiving circuit 131 receives a light signal that is transmitted via an optical fiber 135, converts the received light signal into an electrical signal, and outputs the electrical signal.

The light communication system 130 according to the present embodiment includes a transmission device 131, an optical fiber 135, and a receiving device 140. The transmission device 131 includes a drive circuit 132, and a light emitting element 133 that is driven by the drive circuit 132. The light emitting element 133 of the transmission device 131 is optically coupled to an end portion of the optical fiber 135, and transmits a light signal. The other end portion of the optical fiber 135 is optically coupled to a light receiving element 143a of a light receiving circuit 143 of the receiving device 140, and receives the light signal that is transmitted via the optical fiber 135. The receiving device 140 further includes the slew rate control output circuit 1 that drives a load using the digital signal output from the light receiving circuit 143. The light receiving element 143a receives a light signal and converts the light signal into an electric signal, and a trans-impedance amplifier 143b converts an output current from the light receiving element 143a into a voltage signal.

The light communication system 130 according to the present embodiment is connected to the load circuit with a wide range of capacitors and may drive the load circuit so as to have low loss.

According to the embodiments described above, it is possible to achieve an output circuit, a light coupling device, and a light communication system that may drive a wide range of load capacitors with low power consumption at a constant slew rate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An output circuit for receiving an input signal at an input terminal and outputting an output signal at an output terminal, the output circuit comprising:
a first transistor of a first conductivity type having a drain and a source which are connected between a power supply terminal and an output terminal;
a first capacitance element connected between a gate and the drain of the first transistor;
a second transistor of a second conductivity type having a drain and a source which are connected between a reference potential terminal and the output terminal;
a second capacitance element connected between a gate and the drain of the second transistor;
a first drive circuit configured to detect when a gate voltage of the second transistor is at a level which places the second transistor in a non-conducting state and to supply a gate voltage to the first transistor which places the first transistor in a conducting state when the second transistor is in the non-conducting state; and
a second drive circuit configured to detect when the gate voltage of the first transistor is at a level which places the first transistor in a non-conducting state and to supply the gate voltage to the second transistor which places the second transistor in a conducting state when the first transistor is in the non-conducting state.

2. The output circuit according to claim 1, wherein
the second drive circuit is configured to supply the gate voltage to the second transistor which places the second transistor in the conducting state when a voltage between the gate and the source of the first transistor is above a first threshold voltage and the input signal at the input terminal is a low level, and
the first drive circuit is configured to supply the gate voltage to the first transistor which places the first transistor in the conducting state when a voltage between the gate and the source of the second transistor is below a second threshold voltage and the input signal at the input terminal is a high level, wherein the first transistor is non-conducting when the voltage between the gate and source of the first transistor is above the first threshold voltage and the second transistor is non-conducting when the voltage between the gate and source of the second transistor is below the second threshold voltage.

3. The output circuit according to claim 1, wherein
the second drive circuit includes a third transistor, a first output transistor, and a fourth transistor that are connected in series between the power supply terminal and the reference potential terminal, the third transistor being a p-channel transistor with a source connected to the power supply terminal and a drain connected to first output resistor and the gate of the first transistor, the fourth transistor being a n-channel transistor having a drain connected to the gate of the first transistor via the first output resistor and a source connected to the reference potential terminal, the third and fourth transistors having respective gates which are connected to each other and an output of a second transistor gate voltage monitoring circuit, the second transistor gate voltage monitoring circuit being configured to provide a high level signal to the gates of the third and fourth transistors when the input signal at the input terminal is a high level and the gate voltage of the second transistor is below a first threshold value, and
the first drive circuit includes a fifth transistor, a second output transistor, and a sixth transistor that are connected in series between the power supply terminal and the reference potential terminal, the fifth transistor being a p-channel transistor with a source connected to the power supply terminal and a drain connected to the gate of the second transistor via the second output resistor, the sixth transistor being a n-channel transistor having a source connected to the reference potential terminal and a drain connected to the second output resistor and the gate of the second transistor, the fifth and sixth transistors having respective gates which are connected to each other and an output of a first transistor gate voltage monitoring circuit, the first transistor gate voltage monitoring circuit being configured to provide a low level signal to the gates of the fifth and sixth transistors when the input signal at the input terminal is a low level and the gate voltage of the first transistor is above a second threshold value.

4. The output circuit according to claim 3, wherein
the first output resistor is provided by an ON-state resistance at least one transistor of the second conductivity type in a CMOS type inverter in the first drive circuit; and
the second output resistor is provided by an ON-state resistance of at least one transistor of the second conductivity type in a CMOS type inverter in the second drive circuit.

5. The output circuit according to claim 3, wherein a resistance value of the first output resistor is greater than an on-state resistance of the third transistor, and a resistance value of the second output resistor is greater than an on-state resistance of the sixth transistor.

6. The output circuit according to claim 1, wherein the first transistor is a p-channel metal-oxide-semiconductor field effect transistor, and the second transistor is a n-channel metal-oxide-semiconductor field effect transistor.

7. The output circuit according to claim to 6, further comprising:
a delay unit configured to generate a delay signal corresponding to the input signal at the input terminal offset by a predetermined amount of time, wherein
the second drive circuit drives the first transistor according to a logical operation involving the delay signal, the gate voltage of the first transistor, and the input signal; and
the first drive circuit drives the second transistor according to a logical operation involving the delay signal, the gate voltage of the second transistor, and the input signal.

8. The output circuit according to claim 1, further comprising:
a delay unit configured to generate a delay signal corresponding to the input signal at the input terminal offset by a predetermined amount of time, wherein
the second drive circuit drives the first transistor according to a logical operation involving the delay signal, the gate voltage of the second transistor, and the input signal.

9. The output circuit according to claim 1, further comprising:
a delay unit configured to generate a delay signal corresponding to the input signal at the input terminal offset by a predetermined amount of time, wherein
the first drive circuit drives the second transistor according to a logical operation involving the delay signal, the gate voltage of the second transistor, and the input signal.

10. The output circuit according to claim 1, further comprising:
a low voltage protection unit configured to maintain the output signal at a low level when the voltage between the power supply terminal and the reference potential terminal is less than a predetermined voltage level.

11. An output circuit for receiving an input signal and transmitting an output signal, the output circuit comprising:
a first transistor having a first gate, the first transistor connected between a power supply terminal and an output terminal;
a second transistor having a second gate, the second transistor connected between a reference potential terminal and the output terminal;
a third transistor connected between the power supply terminal and the first gate, the third transistor connected to the first gate along a first low resistance path, wherein a first low resistance is equal to an on resistance of the third transistor plus a resistance of the first low resistance path;
a fourth transistor connected between the reference potential terminal and the first gate, the fourth transistor connected to the first gate along a first high resistance path, wherein a first high resistance is equal to an on resistance of the fourth transistor plus a resistance of the first high resistance path;
a first capacitor between the first gate and a first drain of the first transistor;
a fifth transistor connected between the power supply terminal and the second gate, the fifth transistor connected to the second gate along a second high resistance path, wherein a second high resistance is equal to an on resistance of the fifth transistor plus a resistance of the second high resistance path, wherein the second high resistance is higher than the first low resistance;
a sixth transistor connected between the reference potential terminal and the second gate, the sixth transistor connected to the second gate along a second low resistance path, wherein a second low resistance is equal to an on resistance of the sixth transistor plus a resistance of the second low resistance path, wherein the first high resistance is higher than the second low resistance; and
a second capacitor between the second gate and a second drain of the second transistor.

12. The output circuit according to claim 11, wherein the first transistor is a p-channel transistor that is configured to turn on when the fourth transistor turns on and the second transistor is an n-channel transistor that is configured to turn on when the fifth transistor turns on.

13. The output circuit according to claim 11, wherein the second high resistance is at least 15 times higher than the first low resistance and the first high resistance is at least 15 times higher than the second low resistance.

14. The output circuit according to claim 11, further comprising:
a first output resistor between the first gate and the fourth transistor; and
a second output resistor between the second gate and the fifth transistor.

15. The output circuit according to claim 11, further comprising:
a first transistor monitoring circuit connected to the first gate and a gate of each of the fifth and sixth transistors, the first transistor monitoring circuit configured to switch conductance states of the fifth and sixth transistors by supplying a voltage corresponding to a gate voltage at the first gate; and
a second transistor monitoring circuit connected to the second gate and a gate of each of the third and fourth transistors, the second transistor monitoring circuit configured to switch conductance states of the third and fourth transistors by supplying a voltage corresponding to a gate voltage at the second gate.

16. The output circuit according to claim 15, wherein the first transistor, the third transistor, and the fifth transistor are each p-channel metal-semiconductor-oxide field effect transistors, and
the second transistor, the fourth transistor, and the sixth transistor are each n-channel metal-oxide-semiconductor field effect transistors.

17. The output circuit according to claim 11, wherein
the first transistor, the third transistor, and the fifth transistor are each p-channel metal-semiconductor-oxide field effect transistors, and
the second transistor, the fourth transistor, and the sixth transistor are each n-channel metal-oxide-semiconductor field effect transistors.

18. The output circuit according to claim 15, further comprising a delay unit having an input connected to the input signal and an output connected to the first monitoring circuit and the second monitoring circuit, wherein the output of the delay unit is the input signal delayed by a predetermined amount of time.

19. The output circuit according to claim 11, further comprising a low voltage protection unit configured to maintain the output signal at a low level when a voltage between the power supply terminal and the reference potential terminal is below a predetermined voltage level.

20. A light coupling device, comprising:
a light emitting element to generate a light signal;
a light receiving element to generate an input signal based on the light signal; and
an output circuit to receive the input signal from the light emitting element and to output an output signal corresponding to the input signal at an output terminal, the output circuit comprising:
a first transistor of a first conductivity type having a drain and a source which are connected between a power supply terminal and an output terminal;
a first capacitance element connected between a gate and the drain of the first transistor;
a second transistor of a second conductivity type having a drain and a source which are connected between a reference potential terminal and the output terminal;
a second capacitance element connected between a gate and the drain of the second transistor;
a first drive circuit configured to detect when a gate voltage of the second transistor is at a level which places the second transistor in a non-conducting state and to supply a gate voltage to the first transistor which places the first transistor in a conducting state when the second transistor is in the non-conducting state; and
a second drive circuit configured to detect when the gate voltage of the first transistor is at a level which places the first transistor in a non-conducting state and to supply the gate voltage to the second transistor which places the second transistor in a conducting state when the first transistor is in the non-conducting state.
